(19) United States
(12) Patent Application Publication
(10) Pub. No.: US 2026/0279303 A1
(43) Pub. Date: Sep. 17, 2026

(54) DISPLAY PANEL AND DISPLAY DEVICE

(71) Applicants: Beijing BOE Display Technology Co., Ltd., Beijing (CN); BOE Technology Group Co., Ltd., Beijing (CN)

(72) Inventors: Wei QIN, Beijing (CN); Pengfei HU, Beijing (CN); Yingmeng MIAO, Beijing (CN); Dongchuan CHEN, Beijing (CN); Yanping LIAO, Beijing (CN); Seungmin LEE, Beijing (CN); Yue YANG, Beijing (CN)

(21) Appl. No.: 18/727,178

(22) PCT Filed: Apr. 23, 2023
(86) PCT No.: PCT/CN2023/090042

§ 371 Date: Apr. 29, 2026

(51) Int. Cl. G09G 3/36; G02F 1/1333; G02F 1/1362; G09G 3/34; H10D 86/40; H10D 86/60

(52) U.S. Cl. CPC G09G 3/3696; G02F 1/13338; G02F 1/136286; G09G 3/342; H10D 86/441; H10D 86/481; H10D 86/60; G02F 2203/21; G09G 2300/0426; G09G 2330/045; G09G 2360/145

(57) ABSTRACT

A display panel and display device. The display panel includes a display area, and multiple fan-shaped routing areas on a side of the display area, where the display panel includes: multiple gate lines, extending in a first direction, and in the display area; multiple data lines, extending in a second direction, intersecting with the gate lines, and in the display area; multiple routing groups, where one of the routing groups is disposed in one of the fan-shaped routing areas, and part of the routing groups is electrically connected with the data lines; and, a temperature sensor, on a same side of the display area as the fan-shaped routing areas.

### CROSS REFERENCE TO RELATED APPLICATIONS

The present disclosure is a US National Stage of International Application No. PCT/CN2023/090042, filed on Apr. 23, 2023, the entire contents of which are incorporated herein by reference.

### TECHNICAL FIELD

The present disclosure relates to the technical field of semiconductor, and in particular to a display panel and display device.

### BACKGROUND

Liquid crystal display (LCD) is one of mainstream display structures of current displays. At present, liquid crystal displays are mainly based on thin film transistor (TFT) liquid crystal displays. The display panel usually includes a color film substrate and a TFT array substrate arranged opposite to each other, as well as a liquid crystal layer arranged between two substrates.

### SUMMARY

Embodiments of the present disclosure provide a display panel including a display area, and a plurality of fan-shaped routing areas on a side of the display area, where the display panel includes:
a plurality of gate lines, extending in a first direction, and in the display area;
a plurality of data lines, extending in a second direction, intersecting with the plurality of gate lines, and in the display area;
a plurality of routing groups, where at least one of the plurality of routing groups is disposed in at least one of the plurality of fan-shaped routing areas, and at least part of the plurality of routing groups is electrically connected with the plurality of data lines;
at least one temperature sensor, on a same side of the display area as the fan-shaped routing areas, where at least part of the at least one temperature sensor is in an area between two adjacent fan-shaped routing areas;
where the temperature sensor is configured to detect an ambient temperature, so that the display panel loads a voltage on the data lines based on a temperature detected by the temperature sensor.

In a possible embodiment, the display panel includes an array substrate and an opposite substrate disposed opposite to each other, where the temperature sensor is arranged in the array substrate;
the array substrate has a first substrate; the temperature sensor includes a first electrode portion, an active portion disposed on a side of the first electrode portion facing away from the first substrate, and a second electrode portion disposed on a side of the active portion facing away from the first electrode portion; an orthographic projection of the first electrode portion on the first substrate covers an orthographic projection of the active portion on the first substrate, and the orthographic projection of the active portion on the first substrate covers an orthographic projection of at least part of the second electrode portion on the first substrate.

In a possible embodiment, the second electrode portion includes: a first sub-portion and a second sub-portion disposed opposite to each other;
the first sub-portion includes: a first main portion extending in the first direction, and a plurality of first branch portions extending out from the first main portion in the second direction;
the second sub-portion includes: a second main portion extending in the first direction, and a plurality of second branch portions extending out from the second main portion in the second direction; and the first branch portions intersect with the second branch portions.

In a possible embodiment, the at least one temperature sensor includes: two first electrode portions arranged in the first direction, two active portions arranged in the first direction, and two second electrode portions arranged in the first direction;
the two first electrode portions are spaced apart and independent of each other;
the two active portions are spaced apart and independent of each other;
the two second electrode portions share a same first main portion, and the second main portions of the two second electrode portions are spaced apart and independent of each other.

In a possible embodiment, the display panel further includes: a plurality of sensor leads; where the plurality of sensor leads includes: a first routing, where one end of the first routing is electrically connected with the first electrode portion and extends towards a side far away from the display area; a second routing, where one end of the second routing is electrically connected with the first main portion and extends towards the side far away from the display area; and a third routing, where one end of the third routing is electrically connected with the second main portion and extends towards the side far away from the display area;
where the display panel further includes: a pin group electrically connected with the routing group, and a floating pin group on an outside of the pin group; the floating pin group includes a first floating pin, a second floating pin, and a third floating pin;
the other end of the first routing is electrically connected with the first floating pin, the other end of the second routing is electrically connected with the second floating pin, and the other end of the third routing is electrically connected with the third floating pin.

In a possible embodiment, the second routing includes: a first sub-routing portion, and a second sub-routing portion; the third routing includes: a third sub-routing portion, and a fourth sub-routing portion;
where the display panel further includes: a first adapter portion and a second adapter portion; the first sub-routing portion, the second sub-routing portion, and the first adapter portion are on different layers, and the third sub-routing portion, the fourth sub-routing portion, and the second adapter portion are on different layers;
an orthographic projection of the first adapter portion on the first substrate covers an orthographic projection of a part of the first sub-routing portion on the first substrate, and an orthographic projection of a part of the second sub-routing portion on the first substrate; and the first sub-routing portion and the second sub-routing portion are connected through the first adapter portion for conduction;
an orthographic projection of the second adapter portion on the first substrate covers an orthographic projection of a part of the third sub-routing portion on the first substrate, and an orthographic projection of a part of the fourth sub-routing portion on the first substrate; and the third sub-routing portion and the fourth sub-routing portion are connected through the second adapter portion for conduction.

In a possible embodiment, the first sub-routing portion, the third sub-routing portion and the second electrode portion are of a same layer and a same material;
the second sub-routing portion, the fourth sub-routing portion and the first electrode portion are of a same layer and a same material;
the first routing and the first electrode portion are of a same layer and a same material.

In a possible embodiment, the data lines are disposed on one sides of the gate lines facing away from the first substrate; the display panel includes: a pixel electrode and/or a common electrode disposed on one sides of the data lines facing away from the gate lines;
the first electrode portion is of a same layer and a same material as the gate lines;
the second electrode portion is of a same layer and a same material as the data lines;
the first adapter portion and the second adapter portion are of a same layer and a same material as the pixel electrode or common electrode.

In a possible embodiment, at least one of the second sub-routing portion and the fourth sub-routing portion is provided with a plurality of hollow areas.

In a possible embodiment, the pin group includes: a plurality of first sub-pins, and a plurality of second sub-pins disposed on both sides of the plurality of first sub-pins;
the display panel further includes: a common routing, where the data line is electrically connected with the first sub-pin, and the common routing is electrically connected with the second sub-pin.

In a possible embodiment, the common routing is provided with a first hollow portion, at least part of the common routing is in an area between two adjacent fan-shaped routing areas;
an orthographic projection of the temperature sensor on the first substrate is in an orthographic projection of the first hollow portion on the first substrate.

In a possible embodiment, the common routing is further provided with a plurality of second hollow portions, an area of the first hollow portion is larger than an area of the second hollow portion; and the common routing is of a same layer and a same material as the first electrode portion.

In a possible embodiment, a shape of an orthographic projection of the active portion on the first substrate is a rectangle.

In a possible embodiment, the routing group includes a plurality of leads;
a distance between adjacent sensor leads is 1.5 to 5 times of a distance of adjacent leads; and a line width of the sensor lead is 5 to 10 times of a line width of the lead.

In a possible embodiment, the display panel further includes at least one light sensor, where the light sensor is on the same side of the display area as the fan-shaped routing area, and the light sensor is in an area outside of the fan-shaped routing area; and the light sensor is configured to detect brightness to adjust brightness of the display panel based on the detected brightness.

In a possible embodiment, the light sensor has a same structure as the temperature sensor.

In a possible embodiment, the light sensor includes two sub-light sensors;
the display panel further includes a black matrix layer, where the black matrix layer is provided with a first black matrix opening, an orthographic projection of one sub-light sensor of the light sensor on the first substrate is within the first black matrix opening, and the other sub-light sensor is obscured by the black matrix layer.

In a possible embodiment, a shape of an outer contour of the active portion in the sub-light sensor is square.

In a possible embodiment, the display panel has a first symmetry axis; the first symmetry axis passes through a center of the at least one temperature sensor.

In a possible embodiment, the display panel further includes: a first side area opposite to the fan-shaped routing area, a second side area and a third side area which are connected a side, where the fan-shaped routing area is located, with the first side area; the first side area, the second side area, and the third side area are located in an area on one side of the display area;
at least one of the first side area, the second side area and the third side area is provided with the temperature sensor.

In a possible embodiment, the first electrode portion of at least one of the temperature sensor and the light sensor is configured to load a square wave signal to turn on the temperature sensor at intervals of a preset length of time, and/or to turn on the light sensor at intervals of a preset length of time.

Embodiments of the present disclosure further provide a display device, including the display panel as provided in embodiments of the present disclosure.

In a possible embodiment, the display device further includes a first circuit board electrically connected with the display panel; where the first circuit board is provided with a first processor to process a temperature signal detected by the temperature sensor to form a first signal.

In a possible embodiment, the display device further includes a second circuit board on a side of the first circuit board far away from the display panel and electrically connected with the first circuit board;
where the second circuit board includes: a second processor configured to process the first signal to form a second signal;
the display device further includes: a third processor, where the third processor at least stores a first storage table corresponding to a room temperature, a second storage table corresponding to a first threshold, and a third storage table corresponding to a second threshold;
the third processor is configured to call the first storage table, the second storage table, or the third storage table based on the second signal to load a voltage to the data lines according to grayscales of the first storage table, the second storage table, or the third storage table.

In a possible embodiment, the display device further includes a backlight source on a backlight side of the display panel, and a fourth processor;
where the fourth processor is configured to adjust brightness of the backlight source based on a signal detected by the light sensor.

### BRIEF DESCRIPTION OF FIGURES

FIG. 1 is a first schematic diagram of a display panel provided by embodiments of the present disclosure.

FIG. 2A is an enlarged schematic diagram of a temperature sensor 3 in FIG. 1.

FIG. 2B is an equivalent circuit diagram of FIG. 2A.

FIG. 2C is a schematic diagram of a single film of a first electrode portion in FIG. 2A.

FIG. 2D is a schematic diagram of a single film of an active portion in FIG. 2A.

FIG. 2E is a schematic diagram of a single film of a second electrode portion in FIG. 2A.

FIG. 3A is an enlarged schematic diagram of the temperature sensor 3 in FIG. 1.

FIG. 3B is an equivalent circuit diagram corresponding to FIG. 3A.

FIG. 3C is a schematic diagram of a single film of a first electrode portion in FIG. 3A.

FIG. 3D is a schematic diagram of a single film of an active portion in FIG. 3A.

FIG. 3E is a schematic diagram of a single film of a second electrode portion in FIG. 3A.

FIG. 3F shows a transition curve of a temperature sensor as a function of temperature.

FIG. 4 is an enlarged schematic diagram of an area between two fan-shaped routing areas.

FIG. 5 is a cross-section schematic diagram of FIG. 3A at the dashed line EF.

FIG. 6 shows a schematic diagram of a temperature sensor and a common routing surrounding the temperature sensor.

FIG. 7 is an enlarged schematic diagram of FIG. 4 at a dotted circle S1.

FIG. 8 is a second schematic diagram of a display panel provided by embodiments of the present disclosure.

FIG. 9A is a schematic diagram of a light sensor.

FIG. 9B is a schematic diagram of a single film of a first electrode portion in FIG. 9A.

FIG. 9C is a schematic diagram of a single film of an active portion in FIG. 9A.

FIG. 9D is a schematic diagram of a single film of a second electrode portion in FIG. 9A.

FIG. 9E is a schematic diagram of a single film of a black matrix layer in FIG. 9A.

FIG. 10A is an equivalent circuit diagram corresponding to FIG. 9A.

FIG. 10B is a schematic diagram of characteristics of a light sensor changing with illumination.

FIG. 11 is a third schematic diagram of a display panel provided by embodiments of the present disclosure.

### DETAILED DESCRIPTION

In order to make the purpose, technical solutions and advantages of the embodiments of the present disclosure clearer, the technical solutions of the embodiments of the present disclosure will be described clearly and completely in the following in conjunction with the accompanying drawings of the embodiments of the present disclosure. It should be noted that the dimensions and shapes of the figures in the accompanying drawings do not reflect the true proportions, but are only intended to illustrate the contents of the present disclosure. Moreover, the same or similar symbols throughout indicate the same or similar components or components having the same or similar functions. Obviously, the described embodiments are some, but not all, of the embodiments of the present disclosure. Based on the described embodiments of the present disclosure, all other embodiments obtained by a person of ordinary skill in the art without the need for creative labor are within the protection scope of the present disclosure.

Unless otherwise defined, technical or scientific terms used herein shall have their ordinary meaning understood by a person of ordinary skill in the art to which the invention belongs. “First”, “second” and similar words used in the description and the claims of the invention do not indicate any order, quantity or importance, but are only used to distinguish different components. Words such as “include” or “comprise” mean that the elements or objects appearing before the word include the elements or objects listed after the word and their equivalents, without excluding other elements or objects. Words such as “inside”, “outside”, “up”, “down” are only used to express relative positional relationships. When the absolute position of the described object is changed, the relative positional relationship may also be changed accordingly.

The word “about” or “substantially the same” as used herein includes a value stated and means being within an acceptable deviation range relative to a specific value as determined by those of ordinary skill in the art in view of the measurement discussed and errors (i.e. limitations of a measurement system) associated with the measurement of a specific quantity. For example, “substantially the same” can mean that a difference from the value stated is within one or more standard deviation ranges or within ranges of ±30%, 20%, 10%, or 5%.

In the accompanying drawings, the thicknesses of layers, films, panels, regions, etc. are enlarged for the sake of clarity. The illustrative implementations are described herein with reference to sectional views that serve as schematic diagrams of the idealized implementations. In this way, deviations from shapes of the figures will be expected as a result of, for example, manufacturing techniques and/or tolerances. Therefore, the implementations described herein should not be interpreted as being limited to the specific shapes of regions shown herein, but rather include deviations in shapes resulting from, for example, manufacturing. For example, regions illustrated or described as flat regions can typically have rough and/or nonlinear features. In addition, the sharp corners illustrated can be rounded. Therefore, the regions shown in the figures are illustrative in nature, and their shapes are neither intended to illustrate the precise shapes of the regions shown, nor intended to limit the scope of the claims.

In order to keep the following description of embodiments of the present disclosure clear and concise, the present disclosure omits detailed descriptions of well-known functions and components.

The liquid crystal cell is the core of the liquid crystal display, and the display effect of the liquid crystal display is mainly influenced by the liquid crystal cell. The main parameters of the liquid crystal cell include transmittance, contrast, viewing angle, response time, drive voltage, etc. Here, the response time represents the time required for the liquid crystal cell to switch between bright (white) and dark (black) states, driven by a pixel voltage, when the torque of the external electric field overcomes the resistance generated by the elastic coefficient, viscosity, and other factors of liquid crystal molecules. The longer the response time, the easier it is for the human eye to observe the phenomenon of image trailing.

In previous designs, OD (overdrive) technology was used to solve the problem of too long response time. However, the response time of liquid crystal molecules is easily affected by temperature, especially negative liquid crystal molecules. When the ambient temperature of liquid crystal molecules changes, the response time will also change. At this time, the OD setting parameters cannot correspond to the response time after the temperature changes, this may cause problems in the display of the screen. When the temperature decreases, the deflection speed of the liquid crystal molecules becomes slower, the original OD function cannot be satisfied, and the image appears poor tailing. When the temperature rises, the deflection speed of the liquid crystal molecules becomes faster, the original OD function is excessive, and the image appears negative color trailing.

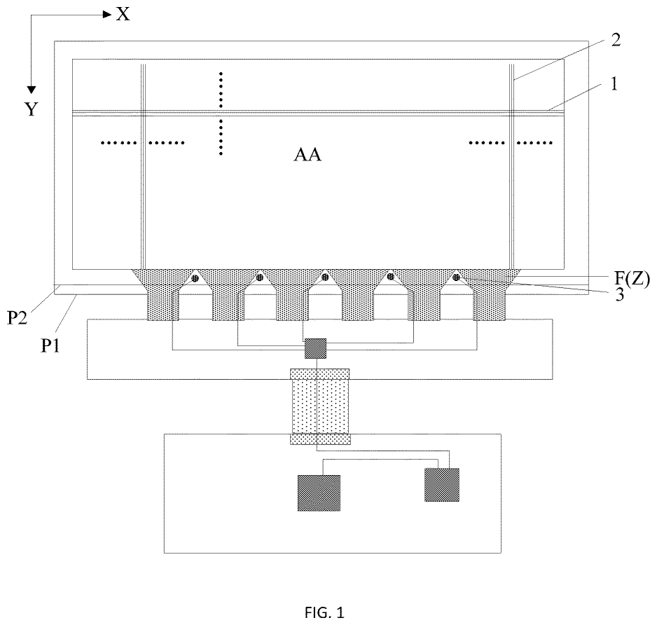

In view of this, embodiments of the present disclosure provide a display panel, as shown in FIG. 1, which has a display area AA and a plurality of fan-shaped routing areas F on one side of the display area AA, where the display panel includes:
a plurality of gate lines 1, extending in a first direction X, and in the display area AA;
a plurality of data lines 2, extending in a second direction Y, intersecting with the gate lines 1, and in the display area AA;
a plurality of routing groups Z, where at least one of the plurality of routing groups Z is located in at least one of the plurality of fan-shaped routing areas F. Specifically, the fan-shaped routing area F corresponds to the routing group Z in one-to-one correspondence, and one routing group Z is arranged in one fan-shaped routing area F. At least part of the routing group(s) Z is electrically connected with the data line(s) 2. The routing group includes multiple routings. The routings in the routing group are electrically connected with the data lines to provide data signals for the data lines; and
at least one temperature sensor 3, on a same side of the display area AA as the fan-shaped routing areas F, where at least part of the temperature sensor(s) 3 is in an area between two adjacent fan-shaped routing areas F;
where the temperature sensor 3 is configured to detect an ambient temperature, so that the display panel loads a voltage on the data lines 2 based on a temperature detected by the temperature sensor 3.

Specifically, when the temperature detected by the temperature sensor 3 is within a first threshold (which can be a temperature range lower than a room temperature), the voltage applied to the data line 2 is greater than a voltage applied at the same gray scale at the room temperature, so as to accelerate the deflection speed of the liquid crystal and avoid poor tailing. When the temperature detected is within a second threshold (which can be a temperature range higher than the room temperature), the voltage applied to the data line 2 is less than the voltage applied at the same gray scale at the room temperature, so as to slow down the deflection speed of the liquid crystal and avoid poor anti-tailing. Specifically, a table of relationships between temperatures and gray scales can be stored in the display device, for example, a first storage table corresponding to the first threshold, a second storage table corresponding to the second threshold, and a third storage table corresponding to the room temperature can be stored, so that when the temperature is detected to be within the first threshold, a voltage can be loaded to the data line 2 according to the first storage table; when the temperature is detected to be within the second threshold, a voltage can be loaded to the data line 2 according to the second storage table; when the temperature is detected to be within the room temperature range, a voltage is applied to the data line 2 according to the third storage table. Specifically, the first threshold can correspond to a temperature lower than the room temperature, and the second threshold can correspond to a temperature higher than the room temperature. Specifically, in a possible embodiment, the first storage table can be an OD parameter table set according to low temperature, the second storage table can be an OD parameter table set according to high temperature, and the third storage table can be an OD parameter table corresponding to the room temperature. The OD parameter table includes grey scale values of the previous frame and the confirmed over drive grey scale values corresponding to the grey scale of the current frame. For example, the grey scale of the previous frame includes 0, 8, 16, 24, 32, 40, 48, . . . , 240, 248, 255 grey scales (7 grey scales per interval, of course, other interval grey scales can also be set, which is not limited here); the gray scale of the current frame includes 0, 8, 16, 24, 32, 40, 48, . . . , 240, 248, 255 grayscale (7 grey scales per interval, of course, other interval grey scales can also be set, which is not limited here). For example, if the gray scale of the previous frame is 32 and the gray scale of the current frame is 64, the corresponding gray scale of the OD gray scale table is 84 (the gray scale of the current frame is greater than the gray scale of the previous frame, and the OD gray scale can be greater than the gray scale of the current frame). For example, if the gray scale of the previous frame is 168 and the gray scale of the current frame is 40, the corresponding gray scale of the OD gray scale table is 38 (the gray scale of the current frame is smaller than the gray scale of the previous frame, and the OD gray scale can be smaller than the gray scale of the current frame). The gray scale of the current frame is equal to the gray scale of the previous frame, and the OD gray scale can be equal to the gray scale of the current frame. It should be noted that in this case, multiple OD parameter tables can be stored, and different OD parameter tables can be called according to different temperatures or temperature ranges, so as to provide the data signals for the data lines in the display area. Of course, only two OD parameter tables can be stored, that is, two versions of parameter tables corresponding to the high temperature (such as 50^{~}60° C.) and the low temperature (−40^{~}−30° C.), the parameter tables corresponding to other temperatures are generated based on the measured temperature, the high and low temperature parameter tables, which can reduce the storage of the storage tables.

In embodiments of the disclosure, the display panel is provided with the temperature sensor 3 on the side where the fan-shaped routing area F is located. The display panel loads the voltage on the data line 2 according to the temperature detected by the temperature sensor 3, so that when the temperature detected by the temperature sensor 3 is lower or higher, the OD tables corresponding to different temperatures are called to ensure that the liquid crystal molecules maintain the same (normal) deflection speed at different temperatures, so that the display panel can adjust the OD parameters in real time according to the change of ambient temperature to ensure the normal display of the screen, so as to solve the problem of OD function failure caused by temperature change and ensure the working performance of the display panel at different temperatures. In addition, compared to setting the temperature sensor 3 on other sides of the display panel, in embodiments of the present disclosure, the temperature sensor 3 is located on the side of the display panel where the fan-shaped routing area F is located, which can avoid the possibility of weak signals detected by the temperature sensor 3. If it is set in an area far from the side where the circuit board is bound to the fan-shaped routing area F, a longer routing will affect the strength of the detected signal, leading to the problem of inaccurate signals. In addition, the temperature sensor 3 is located on the side of the display panel where the fan-shaped routing area F is located, which has little impact on the internal routing of the display panel. And, the routing space between the fan-shaped routing areas of the display panel is large. When the common routing is set in the area between the fan-shaped routings, the common routing can be adjusted to set the temperature sensor. Due to the relatively large area of common routing compared to other display signal lines, adjusting the common routings to set sensors to give new functions to the display panel will not have a significant impact on the signal of the common routing and will not affect the display effect. This can ensure normal display while giving new functions to the display panel, improving display quality.

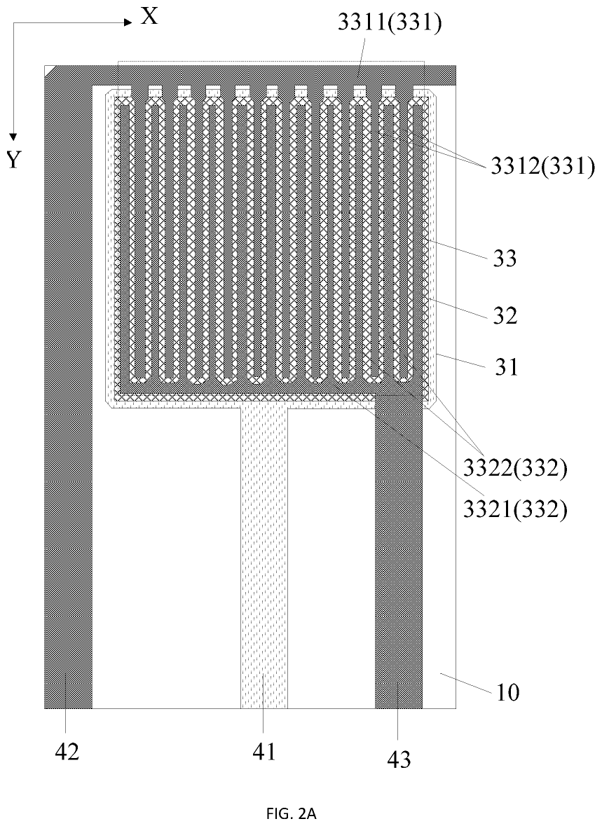

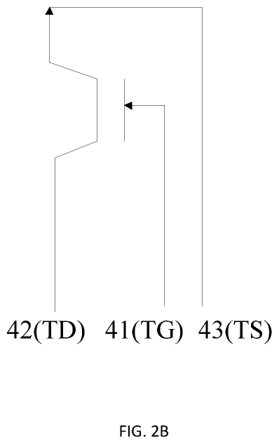

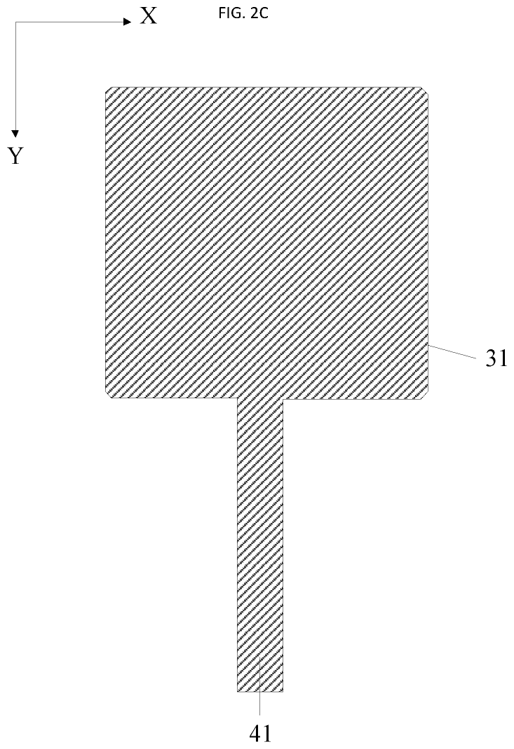

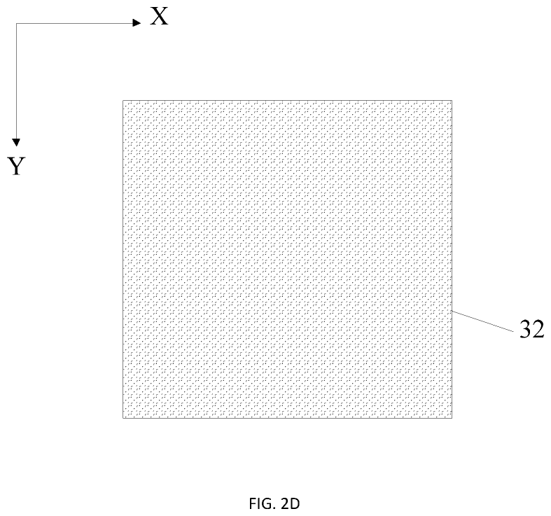

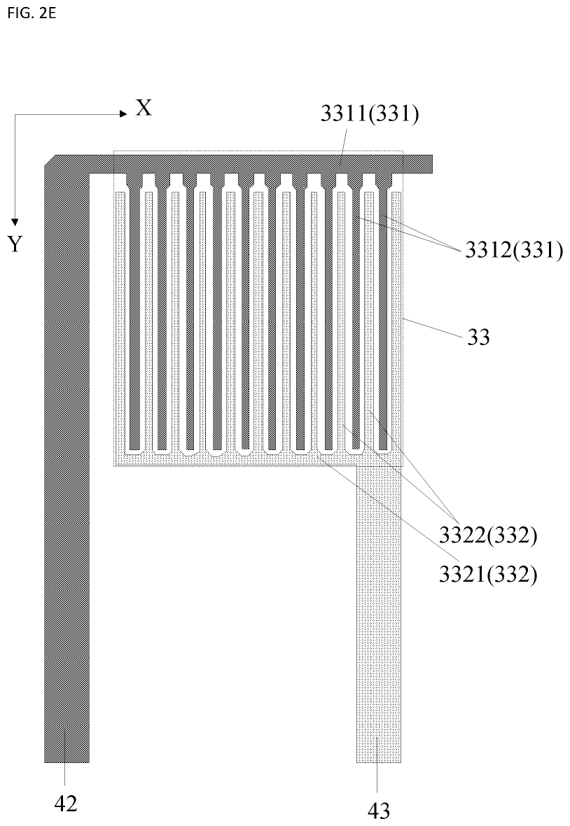

In a possible embodiment, as shown in FIG. 1, FIG. 2A to FIG. 2E, where FIG. 2A is an enlarged schematic diagram of the temperature sensor 3 in FIG. 1; FIG. 2B is an equivalent circuit diagram of FIG. 2A; FIG. 2C is a schematic diagram of a single film of the first electrode portion in FIG. 2A; FIG. 2D is a schematic diagram of a single film of the active portion in FIG. 2A; FIG. 2E is a schematic diagram of a single film of the second electrode portion in FIG. 2A. The display panel includes the array substrate P1 and the opposite substrate P2 arranged opposite to each other, and the temperature sensor 3 is located on the array substrate P1. The array substrate P1 is provided with a first substrate 10, and the temperature sensor 3 includes a first electrode portion 31, an active portion 32 located on the side of the first electrode portion 31 facing away from the first substrate 10, and a second electrode portion 33 located on the side of the active portion 32 facing away from the first electrode portion 31. The orthographic projection of the first electrode portion 31 on the first substrate 10 covers an orthographic projection of the active portion 32 on the first substrate 10, and the orthographic projection of the active portion 32 on the first substrate 10 covers an orthographic projection of at least part of the second electrode portion 33 on the first substrate 10. Specifically, a control signal can be loaded onto the first routing 41 electrically connected with the first electrode portion 31, and a signal corresponding to the temperature can be obtained according to the detected signal between the second routing 42 and the third routing 43 electrically connected with the second electrode portion 33.

Specifically, as shown in FIG. 1, on the side where the fan-shaped routing area F is located, the temperature sensor 3 can be specifically set in the area between the outer edge of the display area AA and the outer edge of the opposite substrate P2.

In a possible embodiment, as shown in FIG. 1, FIG. 2A to FIG. 2E, the second electrode portion 33 includes: a first sub-portion 331 and a second sub-portion 332 disposed opposite to each other; the first sub-portion 331 includes: a first main portion 3311 extending in the first direction, and a plurality of first branch portions 3312 extending out from the first main portion 3311 in the second direction Y; the second sub-portion 332 includes: a second main portion 3321 extending in the first direction X, and a plurality of second branch portions 3322 extending out from the second main portion 3321 in the second direction Y; and the first branch portion(s) 3312 intersects with the second branch portion(s) 3322.

Specifically, as shown in FIG. 2A and FIG. 2B, the temperature sensor 3 can be a transistor, the first electrode portion 31 can be used as the control electrode TG, the first sub-portion 331 can be used as the first electrode TD of the transistor, and the second sub-portion 332 can be used as the second electrode TS of the transistor. The first electrode portion 31 can control the opening or closing of the temperature sensor 3, and by measuring the current signal between the first sub-portion 331 and the second sub-portion 332, the relevant signal detected by the temperature sensor 3 can be obtained. Specifically, the first electrode portion 31 of the temperature sensor 3 can be made of the gate layer metal, the active portion 32 can be made of the semiconductor active layer, and the second electrode portion 33 can be made of the data line layer metal, forming the gate electrode (TG), source electrode (TS), and drain electrode (TD) of the temperature sensor. The channel width-to-length ratio (W/L) of the transistor can be 2500/3.9 (it can be adjusted according to the materials used, design scheme and other factors). In order to increase the detection accuracy of the sensor, the width-to-length ratio of the transistor in the sensor is larger than the width-to-length ratio of the transistor in the display area of the display panel. The transistors in the display area are used to realize electrical connection with the gate line, the data line and the pixel electrode of the display panel. Optionally, in this case, in order to simplify the process, the transistors within the display area, transistors contained in temperature sensors, or transistors contained in light sensors are prepared using the same process, that is, the transistor in the display area and the sensor between the fan-shaped routing areas are prepared with the same layer and the same material.

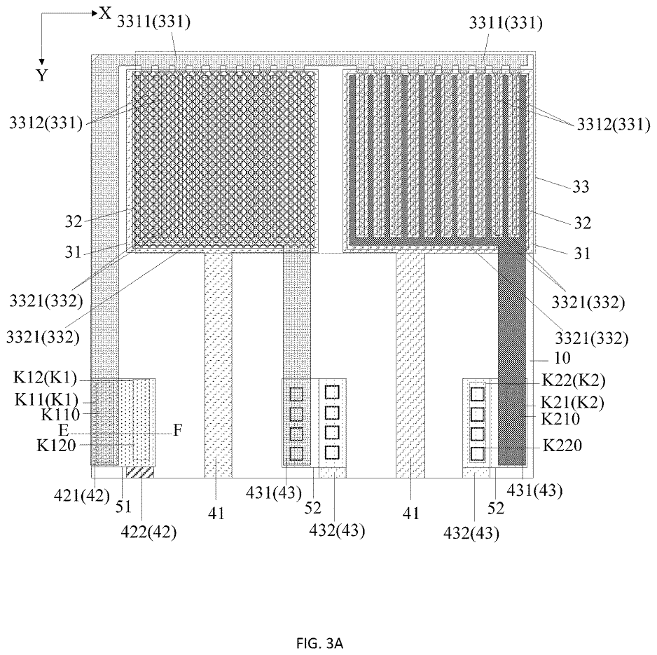

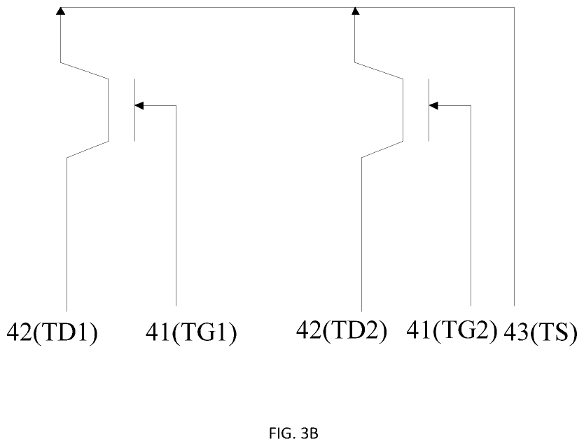

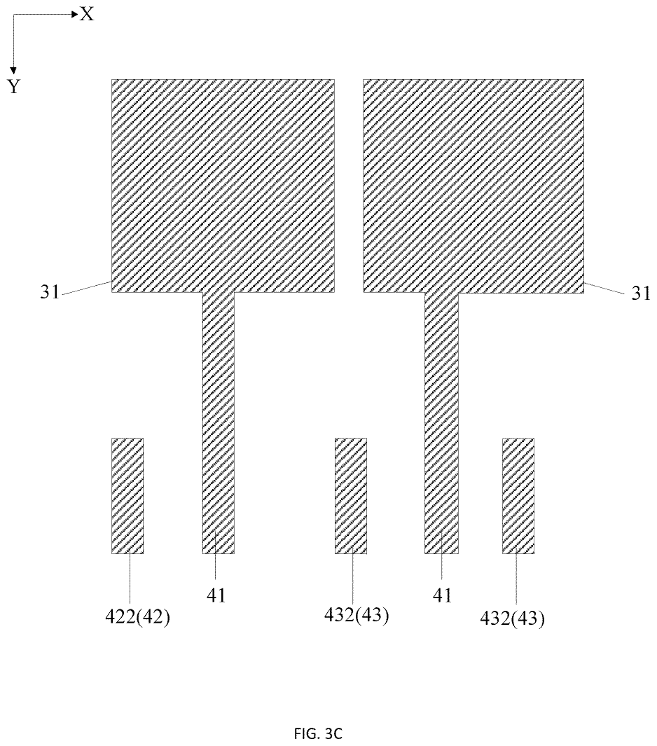

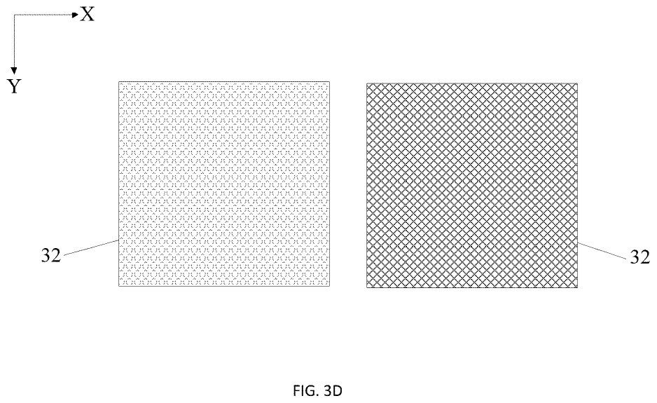

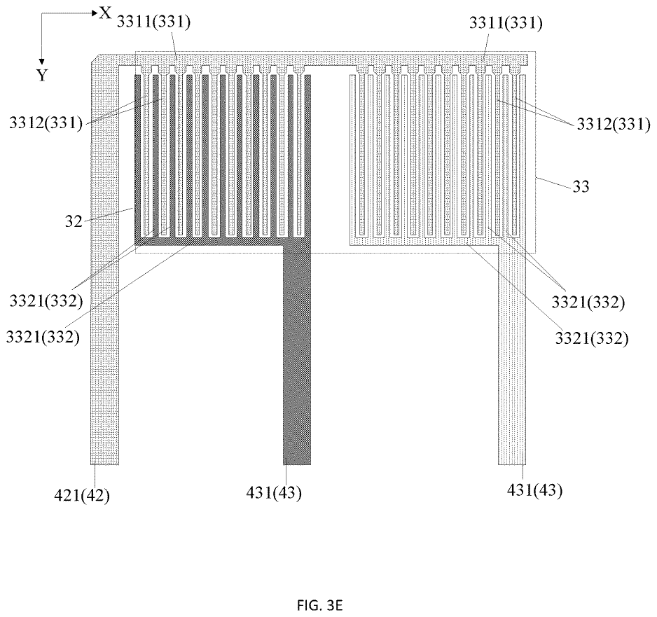

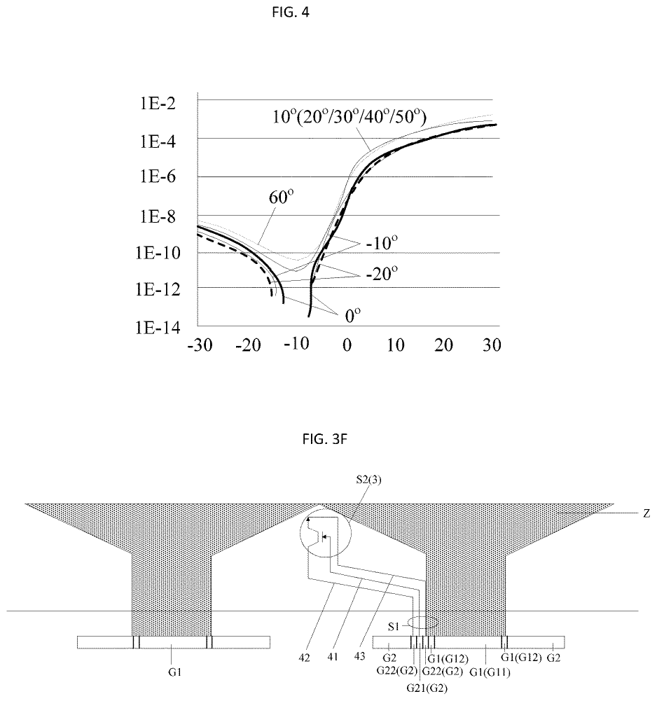

In a possible embodiment, as shown in FIG. 1, FIG. 3A to FIG. 3E, where FIG. 3A is an enlarged schematic diagram of the temperature sensor 3 in FIG. 1; FIG. 3B is an equivalent circuit diagram corresponding to FIG. 3A; FIG. 3C is a schematic diagram of a single film of the first electrode portion in FIG. 3A; FIG. 3D is a schematic diagram of a single film of the active portion in FIG. 3A; FIG. 3E is a schematic diagram of a single film of the second electrode portion in FIG. 3A. The at least one temperature sensor 3 includes: two first electrode portions 31 arranged in the first direction X, two active portions 32 arranged in the first direction X, and two second electrode portions 33 arranged in the first direction X; the two first electrode portions 31 are spaced apart and independent of each other; the two active portions 32 are spaced apart and independent of each other; the two second electrode portions 33 share a same first main portion 3331, and the second main portions 3321 of the two second electrode portions 33 are spaced apart and independent of each other. In embodiments of the disclosure, the temperature sensor 3 adopts a dual transistor structure; and the structure composition and process parameters of the two transistors can be completely consistent. Two transistors use the same first main portion 3331, and the first electrode portion 31 and the second main portion 3321 are used independently. In the specific implementation, as shown in FIG. 3B, only one of the transistors can be set to be in a normal working state, and its three terminal electrodes can be set with appropriate voltage according to the situation (for example, TG1=−8V, TS=0V, TD1=15V), and the other transistor is not working, the voltage condition can be set to TG2=TD2=TS, ensuring that the three terminal potentials are the same, and avoiding characteristic drift. The two transistors periodically switch operating states based on usage time to avoid characteristic drift caused by long-term operation, increase the service life of temperature sensors, and improve the detection accuracy of temperature sensors.

Specifically, as shown in FIG. 3F, FIG. 3F shows a transition curve of the temperature sensor as a function of temperature. When the ambient temperature rises from −20° C. to 60° C., the increase of the on-state current Ion is not obvious, while the increase of the off-state current Ioff is obvious. The off-state current Ioff is more sensitive to temperature changes, but the off-state current Ioff value is small, it is not easy to be detected and is vulnerable to noise. The off-state current Ioff or on-state current Ion can be selected as the detection signal of the temperature sensor according to the specific situation.

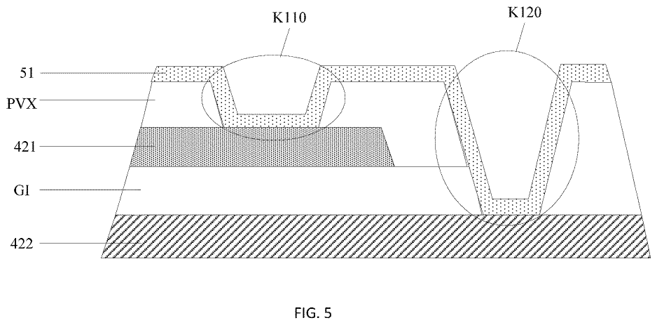

In a possible embodiment, as shown in FIG. 1, FIG. 3A to FIG. 3E and FIG. 4. The display panel also includes: a plurality of sensor leads 4; where the plurality of sensor leads 4 include: a first routing 41, where one end of the first routing 41 is electrically connected with the first electrode portion 31 and extends towards a side far away from the display area AA; a second routing 42, where one end of the second routing 42 is electrically connected with the first main portion 3311 and extends towards the side far away from the display area AA; and a third routing 43, where one end of the third routing 43 is electrically connected with the second main portion 3321 and extends towards the side far away from the display area AA;
the display panel further includes: a pin group G1 electrically connected with the routing group Z, and a floating pin group G2 on an outside of the pin group G1; the floating pin group G2 includes a first floating pin G21, a second floating pin G22, and a third floating pin G23;
the other end of the first routing 41 is electrically connected with the first floating pin G21, the other end of the second routing 42 is electrically connected with the second floating pin G22, and the other end of the third routing 43 is electrically connected with the third floating pin G23.

In embodiments of the disclosure, the sensor lead 4 is electrically connected with the floating pin group G2 located in the outside of the pin group G1, and the floating pin is electrically connected with the floating gold finger on the flexible circuit board. In the conventional display panel, the flexible circuit board electrically connected with the display panel will be provided with some floating gold fingers, and the floating gold finger does not provide signals. In this case, the floating gold finger of the flexible circuit board can be used to transmit the signal of the set sensor, that is, by setting the floating pin corresponding to the floating gold finger of the flexible circuit board on the display panel, the floating pin and the floating gold finger can be electrically connected to transmit the signal. In this way, the existing flexible circuit board can be compatible with the sensors in this case, achieving signal transmission, avoiding the configuration of new flexible circuit boards or gold fingers, and avoiding increasing the production cost of display panels. When the display panel includes multiple flexible circuit boards, the floating gold fingers of some flexible circuit boards can be electrically connected with the floating pins of the display panel and used to transmit electrical signals.

In a possible embodiment, as shown in FIG. 4, the pin group G1 includes: a plurality of first sub-pins G11, and a plurality of second sub-pins G12 disposed on both sides of the plurality of first sub-pins G11; the display panel further includes: a common routing 6 (the common routing is arranged between adjacent fan-shaped routing areas, not shown in FIG. 4), where the data line 2 is electrically connected with the first sub-pin G11, and the common routing 6 is electrically connected with the second sub-pin G12.

In a possible embodiment, referring to FIG. 3A to FIG. 3E and FIG. 5, where FIG. 5 can be a cross-section schematic diagram of FIG. 3A at the dashed line EF, the second routing 42 includes: a first sub-routing portion 421, and a second sub-routing portion 422; the third routing 43 includes: a third sub-routing portion 431, and a fourth sub-routing portion 432;
the display panel further includes: a first adapter portion 51 and a second adapter portion 52; the first sub-routing portion 421, the second sub-routing portion 422, and the first adapter portion 51 are on different layers; and the third sub-routing portion 431, the fourth sub-routing portion 432, and the second adapter portion 52 are on different layers;
an orthographic projection of the first adapter portion 51 on the first substrate 10 covers an orthographic projection of a part of the first sub-routing portion 421 on the first substrate 10, and an orthographic projection of a part of the second sub-routing portion 422 on the first substrate 10; and the first sub-routing portion 421 and the second sub-routing portion 422 are connected through the first adapter portion 51 for conduction; an orthographic projection of the second adapter portion 52 on the first substrate 10 covers an orthographic projection of a part of the third sub-routing portion 431 on the first substrate 10, and an orthographic projection of a part of the fourth sub-routing portion 432 on the first substrate 10; and the third sub-routing portion 431 and the fourth sub-routing portion 432 are connected through the second adapter portion 52 for conduction.

In embodiments of the present disclosure, the second routing 42 includes: a first sub-routing portion 421 and a second sub-routing portion 422; the third routing 43 includes: a third sub-routing portion 431 and a fourth sub-routing portion 432. The first sub-routing portion 421 and the second sub-routing portion 422 are connected through a first adapter portion 51 for conduction, and the third sub-routing portion 431 and the fourth sub-routing portion 432 are connected through a second adapter portion 52 for conduction. That is, when the sensor lead 4 is close to the circuit board side, it can be connected to different layers. In this case, the sensor lead 4 can be placed on the same layer as the common routing, both on the same layer as the gate line, making it convenient to introduce the sensor lead to the position of the solder pad.

Specifically, as shown in FIG. 3A to FIG. 3E and FIG. 5, the array substrate can also include a first hole K1 and a second hole K2, where the first hole K1 includes a first hole group K11 arranged along the first direction X and a second hole group K12 arranged along the first direction X, where the first hole group K11 includes a plurality of first sub-holes K110 arranged along the second direction Y, and the second hole group K12 includes a plurality of second sub-holes K120 arranged along the second direction Y. The first adapter portion 51 is connected with the first sub-routing portion 421 through the first sub-hole K110 for conduction, and the first adapter portion 51 is connected with the second sub-routing portion 422 through the second sub-hole K120 for conduction, thus realizing the electrical connection between the first sub-routing portion 421 and the second sub-routing portion 422. The second hole K2 includes the third hole group K21 arranged along the first direction X and the fourth hole group K22 arranged along the first direction X, where the third hole group K21 includes a plurality of third sub-holes K210 arranged along the second direction Y, and the fourth hole group K22 includes a plurality of fourth sub-holes K220 arranged along the second direction Y. The second adapter portion 52 is connected with the third sub-routing portion 431 through the third sub-hole K210 for conduction, and the second adapter portion 52 is connected with the fourth sub-routing portion 432 through the fourth sub-hole K220 for conduction, thus realizing the electrical connection of the third sub-routing portion 431 and the fourth sub-routing portion 432. In embodiments of the present disclosure, the first hole K1 includes a plurality of first sub-holes K110 and a plurality of second sub-holes K120, which can achieve good conduction between the first adapter portion 51 and the first sub-routing portion 421, and the second hole K2 includes a plurality of third sub-holes K210 and a plurality of fourth sub-holes K220, which can achieve good conduction between the second adapter portion 52 and the fourth sub-routing portion 432.

In a possible embodiment, as shown in FIG. 3A to FIG. 3E and FIG. 5, the first sub-routing portion 421, the third sub-routing portion 431 and the second electrode portion 33 are of a same layer and a same material; the second sub-routing portion 422, the fourth sub-routing portion 432 and the first electrode portion 31 are of a same layer and a same material; the first routing 41 and the first electrode portion 31 are of a same layer and a same material. In this way, the problem of OD function failure caused by temperature change can be reduced, and the performance of the display panel at different temperatures can be guaranteed without increasing the production process of the display panel.

In a possible embodiment, as shown in FIG. 3A-FIG. 3E and FIG. 5, the data lines 2 are disposed on one sides of the gate lines 1 facing away from the first substrate 10; the display panel includes: a pixel electrode and/or a common electrode disposed on one sides of the data lines 2 facing away from the gate lines 1; the first electrode portion 31 is of a same layer and a same material as the gate line 1; the second electrode portion 33 is of a same layer and a same material as the data line 2; the first adapter portion 51 and the second adapter portion 52 are of a same layer and a same material as the pixel electrode layer or common electrode. In this way, the problem of OD function failure caused by temperature change can be reduced, and the performance of the display panel at different temperatures can be guaranteed without increasing the production process of the display panel.

Specifically, as shown in FIG. 5, the gate insulation layer GI can be provided between the gate line 1 and data line 2, the passivation layer PVX can be provided between the data line 2 and the pixel electrode and/or common electrode, the first sub-hole K110 and the third sub-hole K210 can penetrate through the passivation layer PVX; the second sub-hole K120 and the fourth sub-hole K220 can penetrate through the passivation layer PVX and the gate insulation layer GI.

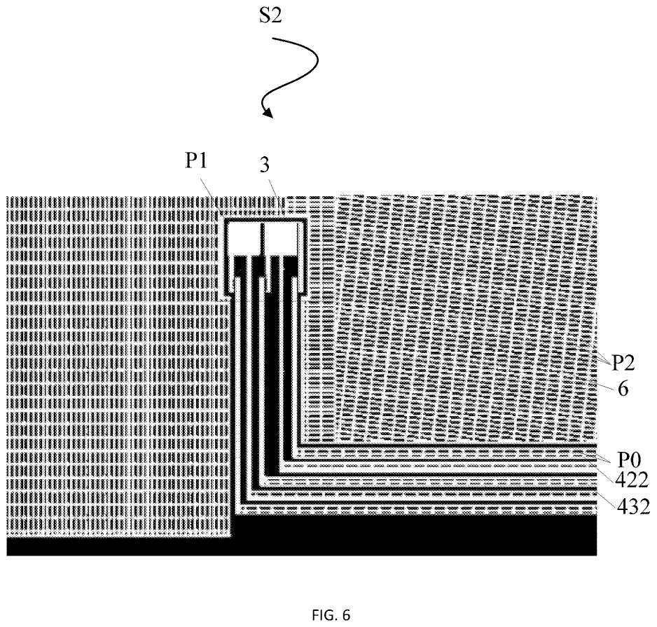

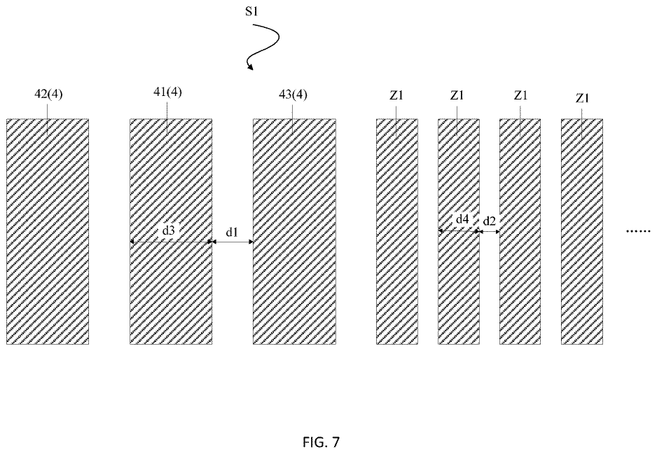

In a possible embodiment, as shown in FIG. 6, FIG. 6 can be an enlarged schematic diagram of FIG. 4 at dotted circle S2. At least one of the second sub-routing portion 422 and the fourth sub-routing portion 432 has a plurality of hollow areas P0. In embodiments of the present disclosure, since the second sub-routing portion 422 and the fourth sub-routing portion 432 are located in the outer area of the display area AA, this area is covered by the frame sealant. The second sub-routing portion 422 and the fourth sub-routing portion 432 are provided with a plurality of hollow areas P0, so that the ultraviolet light for curing the frame sealant can pass through the second sub-routing portion 422 and the fourth sub-routing portion 432, in order to avoid the problem that the frame sealant cannot be cured normally by ultraviolet light.

In a possible embodiment, as shown in FIG. 6, the common routing 6 is provided with a first hollow portion P1, at least part of the common routing 6 is in an area between two adjacent fan-shaped routing areas F; an orthographic projection of the temperature sensor 3 on the first substrate 10 is in an orthographic projection of the first hollow portion P1 on the first substrate 10. In embodiments of the present disclosure, the temperature sensor 3 is arranged at the first hollow portion P1 of the common routing 6, which can make the common routing 6 compact with the temperature sensor 3, and is conducive to the uniformity of metal lithography at this location.

In a possible embodiment, as shown in FIG. 6, the common routing 6 is further provided with a plurality of second hollow portions P2, an area of the first hollow portions P1 is larger than an area of the second hollow portion P2; and the common routing 6 is of a same layer and a same material as the first electrode portions 31. In embodiments of the present disclosure, since the common routing 6 is located in the outer area of the display area AA, which is covered by the frame sealant, the common routing 6 has a plurality of second hollow parts P2, which can enable the ultraviolet light for curing the frame sealant to pass through the common routing 6, avoiding the problem that the frame sealant cannot be cured normally by ultraviolet light.

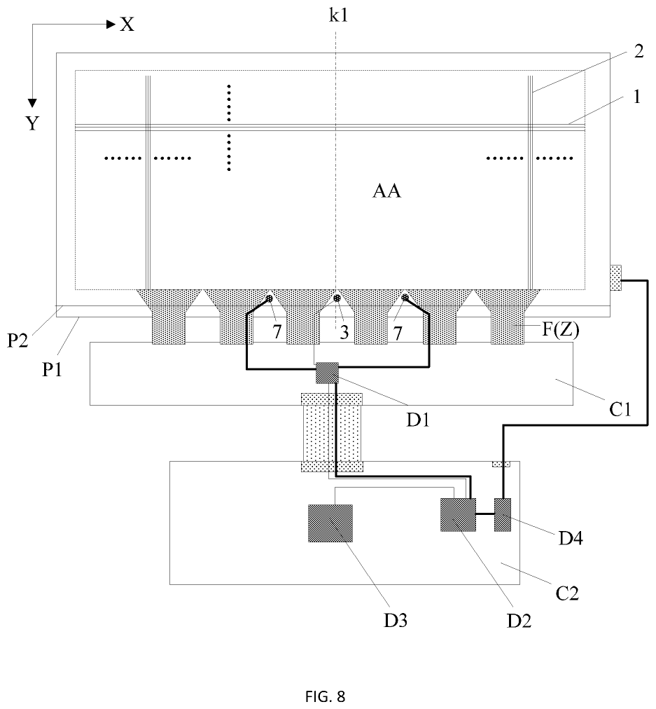

In a possible embodiment, as shown in FIG. 7, FIG. 7 can be an enlarged schematic diagram of FIG. 4 at dotted circle S1, the routing group Z includes a plurality of leads Z1; a distance d1 between adjacent sensor leads 4 is 1.5 to 5 times of a distance d2 between adjacent leads Z1. Since there are many leads in the fan-shaped routing area, in order to reduce the width of the frame, the density of the leads will be set higher, and the line distance will be smaller on the premise of ensuring the stability of the process, for example, 3 μm^{~}8 μm. The line width d3 of the sensor lead 4 is 5 to 10 times of the line width d4 of the lead Z1. Specifically, the distance d2 between adjacent leads Z1 in the routing group Z can be 3 μm^{~}8 μm. Specifically, for example, it can be 3 μm, 4 μm, 5 am, 5.3 μm, 6 μm, 7 μm, 8 μm. The distance d1 between the sensor leads 4 and the distance between the signal lines of the gate drive circuit (such as the clock signal line) can be equal. The signal line of the gate drive circuit extends longer in the non-display area. For example, the clock signal line transmits an AC signal, so the signal lines will be coupled with each other. The distance between the clock signal lines cannot be closer when the non-display frame is reduced. Since the sensor leads need to detect or feedback signals to avoid coupling effects between signal lines, the distance between the sensor leads and the distance between the signal lines of the gate drive circuit can be consistent. Specifically, the distance d1 between the sensor leads 4 can be 10 μm^{~}20 μm. Specifically, for example, it can be 10 μm, 11 μm, 15 μm, 16 μm, 17 μm, 18 μm, 20 μm. The line width d3 of the sensor lead 4 can be 40 μm^{~}60 am. Specifically, for example, it can be 40 μm, 42 μm, 48 μm, 50 μm, 52 μm, 54 μm, 60 μm. The line width d4 of the lead Z1 in the routing group Z can be 5 μm^{~}10 μm. Specifically, for example, it can be 5 μm, 6 μm, 6.5 μm, 7 μm, 7.5 μm, 9 μm, 10 μm.

In a possible embodiment, as shown in FIG. 1 and FIG. 3A to FIG. 3E, a shape of an orthographic projection of the active portion 32 on the first substrate 10 is a rectangle. Specifically, the shape of the orthographic projection of the active portion 32 on the first substrate 10 is a square, that is, the side length of the active portion 32 along the first direction X is equal to the side length of the active portion 32 along the second direction Y. In embodiments of the present disclosure, the shape of the orthographic projection of the active portion 32 on the first substrate 10 is a rectangle, which can make the temperature sensor can be square as a whole, and it is difficult to observe from the outside. When the temperature sensor is rectangular, if there is no black matrix obstruction, due to the reflection of the metal layer, bright strips may be observed from the outside.

In a possible embodiment, as shown in FIG. 1, FIG. 3A to FIG. 3E, a shape of an orthographic projection of the first electrode portion 31 on the first substrate 10 is a rectangle. Specifically, the shape of the orthographic projection of the first electrode portion 31 on the first substrate 10 is a square, that is, the side length of the first electrode portion 31 along the first direction X is equal to the side length of the first electrode portion 31 along the second direction Y. In this way, the temperature sensor can be square as a whole, which is difficult to be observed from the outside. When the shape of the temperature sensor is rectangular, a more obvious bright strip can be observed from the outside.

In a possible embodiment, as shown in FIG. 8, the display panel also includes at least one light sensor 7, where the light sensor 7 is on the same side of the display area AA as the fan-shaped routing area F, and the light sensor 7 is in an area outside of the fan-shaped routing area F; and the light sensor 7 is configured to detect brightness to adjust brightness of the display panel based on detected brightness. Referring to FIG. 8, it is shown that the light sensor 7 and the temperature sensor 3 are respectively set between different fan-shaped routing areas, or both can be set between adjacent fan-shaped routing areas, that is, the light sensor 7 and the temperature sensor 3 are both set in the corresponding area of the temperature sensor 3 in FIG. 8, which is not limited here.

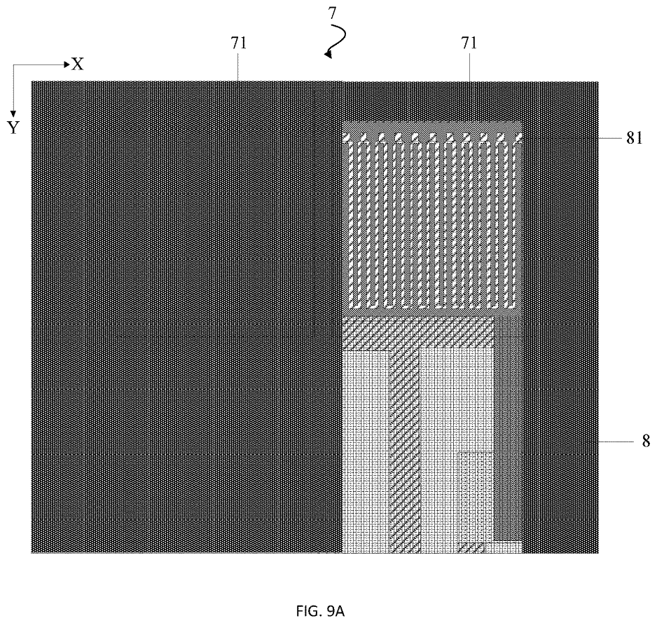

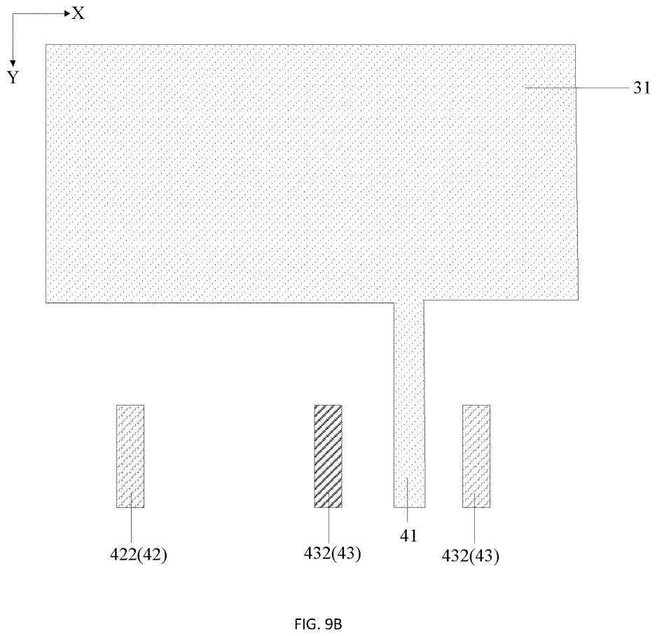

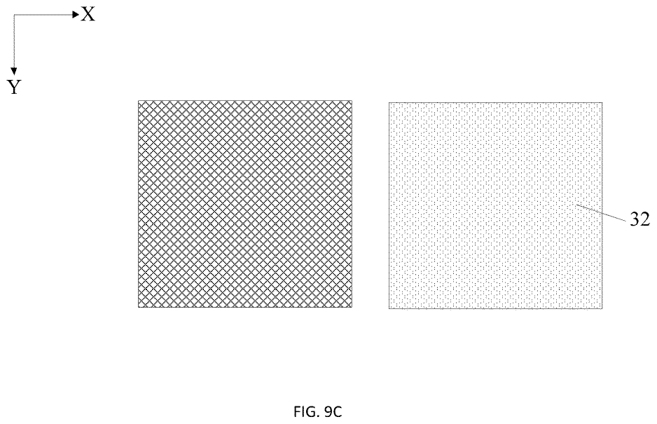

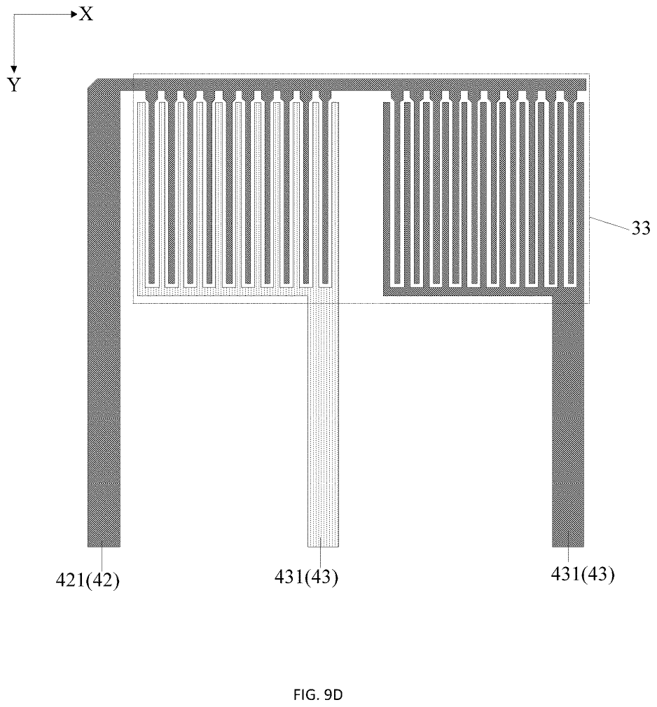

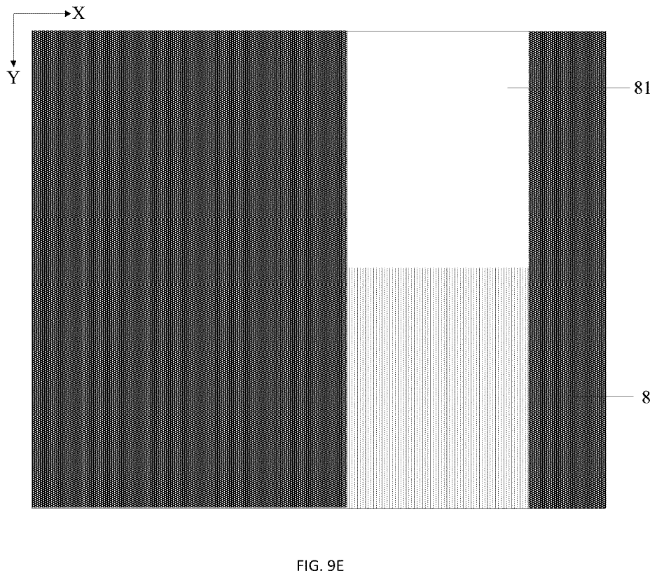

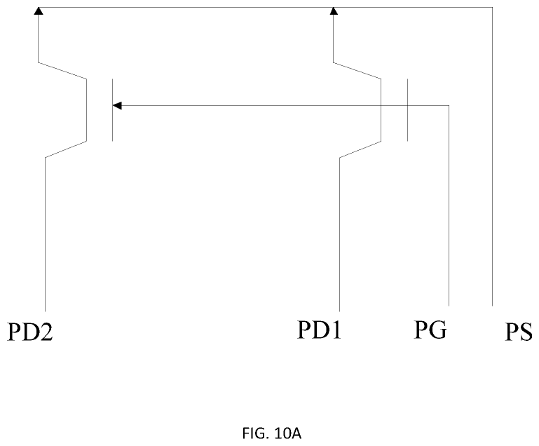

In a possible embodiment, as shown in FIG. 9A to FIG. 9E, where FIG. 9B is a schematic diagram of a single film of the first electrode portion in FIG. 9A; FIG. 9C is a schematic diagram of a single film of the active portion in FIG. 9A; FIG. 9D is a schematic diagram of a single film of the second electrode portion in FIG. 9A; FIG. 9E is a schematic diagram of a single film of the black matrix layer in FIG. 9A. The structure of the light sensor 7 is the same as that of the temperature sensor 3, this can simplify the preparation process and make the display panel compatible with the temperature detection and the light detection. In addition, in the case of that the structure of the light sensor is the same as that of the temperature sensor, it can also be used as a temperature sensor when temperature detection is required, and as a light sensor when light brightness detection is required, that is, the temperature sensor is compatible with the light sensor, enabling the production of two different functional devices in one process. Optionally, the temperature sensor and the light sensor can both be set at a corresponding position between two adjacent fan-shaped routing areas, or they can be set at different positions between two adjacent fan-shaped routing areas. In this case, both the temperature sensor and the light sensor are set in the display panel. Through simple preparation process, the panel can be compatible with two functions, improving the display quality and the integration of the display panel.

Specifically, the structure of the light sensor 7 is the same as that of the temperature sensor 3. The structure of light sensor 7 can be completely consistent with the composition of the film layer, the pattern shape of each film layer, and the process parameters of the temperature sensor 3. Of course, in specific implementation, the structure of the light sensor 7 can also be partially different from the composition of the film layer and the pattern shape of each film layer of the temperature sensor 3. Specifically, for example, as shown in FIG. 9A and FIG. 9B, the first electrode portion 31 of the two sub-light sensors 71 can be an integrated communication structure.

In a possible embodiment, as shown in FIG. 9A to FIG. 9E, the light sensor 7 includes two sub-light sensors 70; the display panel further includes a black matrix layer 8, where the black matrix layer 8 is provided with a first black matrix opening 81, an orthographic projection of a sub-light sensor 70 of the light sensor 7 on the first substrate 10 is within the first black matrix opening 81, and the other of the sub-light sensors 71 is obscured by the black matrix layer 8. In embodiments of the present disclosure, the light sensor 7 also adopts a dual transistor structure, and the process parameters of the two transistors are completely consistent with the temperature sensor. One of the sub-light sensors 71 is not covered by the black matrix (that is, it is located in the area where the first black matrix opening 81 is located), that is, one of the sub-light sensors 71 can be exposed to ambient light, and the other sub-light sensor 71 cannot be exposed to ambient light, and the external light intensity is measured by the brightness difference between the two. In this case, the black matrix can be set on the opposite substrate which is opposite to the array substrate, or on one side of the array substrate, which is not limited here.

In a possible embodiment, as shown in FIG. 9A, a shape of an outer contour of the active portion in the sub-light sensor 71 is square. In this way, the bright strip problem caused by the reflection of the metal layer in the area without black matrix cover can be avoided.

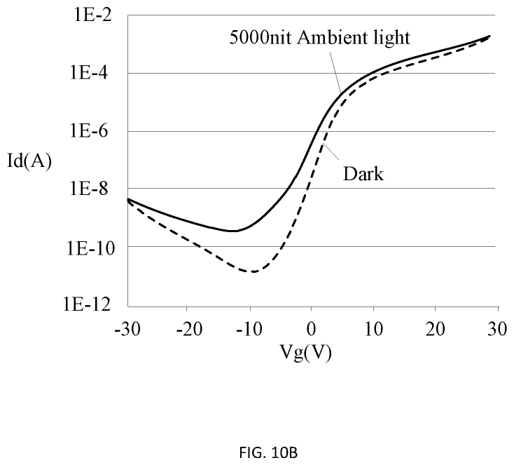

Specifically, as shown in FIG. 10A, specifically, FIG. 10A can be the equivalent circuit diagram of FIG. 9A. The sub-light sensor 71 is a three terminal field-effect transistor structure, and the three terminals are PS, PG, and PD. The two sub-light sensors 71 use the same PS and PG electrodes, and the PD electrodes are used independently.

Specifically, as shown in FIG. 10B, the characteristics of the light sensor change with the light. When the ambient light changes from darkness to 5000 nit, the increase of the on-state current Ion is not obvious, and the increase of the off-state current Ioff is obvious. The off-state current Ioff is more sensitive to the changes of ambient light, but the current value is small and difficult to capture. During normal operation, PG can be set to −8V (the point where the light sensor is most sensitive to light can be adjusted according to the external driving circuit conditions, and the point where the sensor is most sensitive to light under different process conditions may be different). PS can be set to 0V, PD1 and PD2 can be set to 15V. After being illuminated by the ambient light, the current value of the sub-light sensor 71 at the first black matrix opening 81 increases compared to the sub light sensor 71 at the obstruction of the black matrix, and the increase value is proportional to the light intensity. The current difference between PD1 and PD2 is taken as the reference value under the ambient light condition to adjust the backlight brightness.

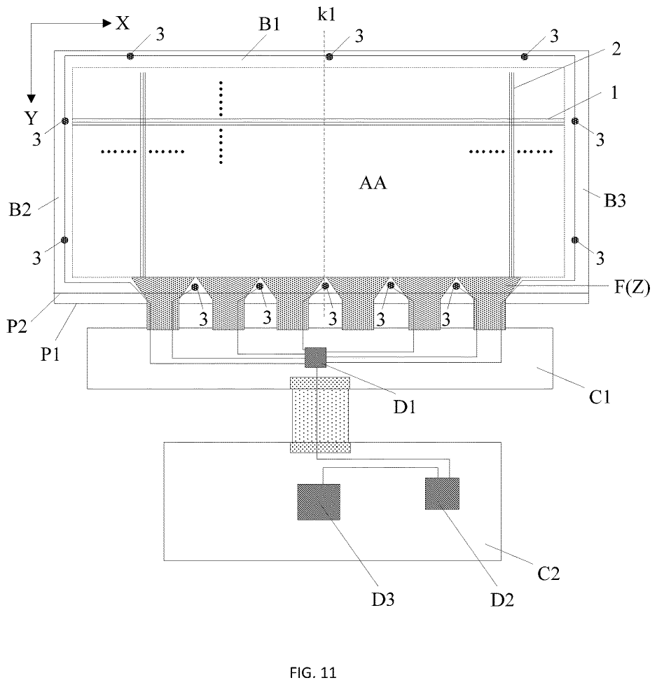

In a possible embodiment, as shown in FIG. 11, the display panel has a first symmetry axis k1; the first symmetry axis k1 passes through a center of the at least one temperature sensor 3.

In a possible embodiment, as shown in FIG. 11, the display panel also includes a first side area B1 opposite to the fan-shaped routing area F, a second side area B2 and a third side area B3 which are connected a side, where the fan-shaped routing area F is located, with the first side area B1; the first side area B1, the second side area B2, and the third side area B3 are located in an area on one side of the display area AA; at least one of the first side area B1, the second side area B2, the third side area B3 is provided with the temperature sensor 3. In embodiments of the present disclosure, in addition to the temperature sensor 3 on the side where the fan-shaped routing area F is located, the temperature sensors 3 are also set in the first side area B1, the second side area B2, and the third side area B3, which can effectively improve the detection accuracy. Especially for large size display products, the temperatures at different locations may have large differences.

In a possible embodiment, the first electrode portion 31 of at least one of the temperature sensor 3 and the light sensor 7 is configured to load a square wave signal to turn on the temperature sensor 3 at intervals of a preset length of time, and/or to turn on the light sensor 7 at intervals of a preset length of time. Specifically, the first electrode portion of the temperature sensor 3 or the first electrode portion of the light sensor 7 is loaded with a square wave (AC) signal, which means that temperature sensor 3 or light sensor 7 is turned on at a preset interval of time, such as 10 seconds, to prevent the transistor from being turned on continuously, causing drift of the temperature sensor 3 and the light sensor 7. The square wave signal, for example, is a PWM signal.

Specifically, the display area AA can be provided with a pixel circuit, which can include a pixel circuit transistor. The film layers of the temperature sensor 3 and the light sensor 7, and can be made in the same layer and process as the corresponding film layers of the pixel circuit transistor.

Based on the same inventive concept, embodiments of the present disclosure also provide a display device, including the display panel provided in embodiments of the present disclosure.

In a possible embodiment, as shown in FIG. 1, FIG. 8 and FIG. 11, the display device further includes a first circuit board C1 electrically connected with the display panel; the first circuit board C1 is provided with a first processor D1 to process the temperature signal detected by the temperature sensor 3 to form a first signal. Specifically, the first circuit board C1 can be a printed circuit board (PCB), and the first processor D1 can be an operational amplifier (OP) to amplify, add and subtract, and perform differential operations on the signals detected by the temperature sensor 3 or the light sensor 7. For example, differential operations can be performed on the signals received by the two sub-sensors 71 in the light sensor 7 to obtain the external light signals detected after removing interference from other factors.

In a possible embodiment, as shown in FIG. 1, FIG. 8 and FIG. 11, the display device further includes a second circuit board C2 on the side of the first circuit board C1 far away from the display panel and electrically connected with the first circuit board C1;
the second circuit board C2 includes: a second processor D2 configured to process the first signal to form the second signal; the display device further includes a third processor D3, wherein the third processor D3 at least stores a first storage table corresponding to the room temperature, a second storage table corresponding to the first threshold, and a third storage table corresponding to the second threshold; the third processor D3 is configured to call the first storage table, the second storage table or the third storage table based on the second signal to load voltage to the data lines according to the grayscales of the first storage table, the second storage table or the third storage table.

Specifically, the second circuit board C2 can be a logic board. The second processor D2 can be a microcontroller unit (MCU), and the third processor D3 can be a logical processor TCON. The temperature sensor 3 converts the captured temperature signal into a specific target value through MCU, and sends it to the TCON through the 12C line to call the corresponding OD table, and the signal acquisition mode is in-phase proportional amplification.

Specifically, as shown in FIGS. 1, 8 and 11, one end of the first processor D1 can be electrically connected with the temperature sensor 3, the other end can be electrically connected with the second processor D2, and the second processor D2 can be electrically connected with the third processor D3.

In a possible embodiment, as shown in FIG. 8, the display device further includes a backlight source on a backlight side of the display panel, and a fourth processor D4; where the fourth processor D4 is configured to adjust brightness of the backlight source based on a signal detected by the light sensor. The fourth processor D4 can be an LED Driver. Specifically, the fourth processor D4 can be electrically connected with the second processor D2, and connected with the interface of the backlight source of the display panel. The light sensor transmits the received light signal to the MCU processing unit through OP, and the MCU sends the processed target signal to the BLU to adjust the backlight brightness.

The display panel of embodiments of the present disclosure is different from the traditional display panel with OD function. The integrated design of the temperature sensor of the display panel cooperates with OD adjustment, which can ensure the normal display of the panel under high/low temperature conditions and improve the stability of the panel. Different from the conventional external temperature sensor, the temperature sensor of the display panel in embodiments of the present disclosure is integrated inside the display panel, and does not occupy additional space or increase the panel volume. The temperature sensor adopts the bottom gate thin-film transistor structure, which is compatible with the conventional LCD panel process and does not require additional photolithography. The temperature sensor will be made together with other structures in the LCD panel, without increasing production costs. Unlike conventional external temperature sensors, the integrated design circuit driving scheme of the temperature sensor for the display panel in this disclosed embodiment is compatible with the existing LCD panel circuit driving scheme and has minimal changes. The temperature sensor integration design scheme of the display panel in this disclosed embodiment can be compatible with the light sensor integration design, that is, the temperature sensor and the light sensor can be integrated simultaneously on the display panel to expand the functionality of the panel. Without changing the layout of the display panel, the light sensor can be converted into a temperature sensor by adjusting the external drive circuit, which improves the flexibility of the display panel.

Although the preferred embodiments of the present disclosure have been described, those skilled in the art will be able to make additional changes and modifications to these embodiments once the basic inventive concepts are apparent. Therefore, it is intended that the appended claims be construed to include the preferred embodiments and all changes and modifications that fall within the scope of the invention.

Evidently those skilled in the art can make various modifications and variations to the present disclosure without departing from the spirit and scope of the present disclosure. Thus the present disclosure is also intended to encompass these modifications and variations therein as long as these modifications and variations to the present disclosure come into the scope of the claims of the present disclosure and their equivalents.

1-25. (canceled)

26. A display panel, comprising a display area, and a plurality of fan-shaped routing areas on a side of the display area, wherein the display panel comprises:
a plurality of gate lines, extending in a first direction, and in the display area;
a plurality of data lines, extending in a second direction, intersecting with the plurality of gate lines, and in the display area;
a plurality of routing groups, wherein at least one of the plurality of routing groups is disposed in at least one of the plurality of fan-shaped routing areas, and at least part of the plurality of routing groups is electrically connected with the plurality of data lines; and
at least one temperature sensor, on a same side of the display area as the fan-shaped routing areas, wherein at least part of the at least one temperature sensor is in an area between two adjacent fan-shaped routing areas.

27. The display panel according to claim 26, comprising an array substrate and an opposite substrate disposed opposite to each other, wherein the temperature sensor is arranged in the array substrate;
the array substrate has a first substrate;
the temperature sensor comprises a first electrode portion, an active portion disposed on a side of the first electrode portion facing away from the first substrate, and a second electrode portion disposed on a side of the active portion facing away from the first electrode portion; an orthographic projection of the first electrode portion on the first substrate covers an orthographic projection of the active portion on the first substrate, and the orthographic projection of the active portion on the first substrate covers an orthographic projection of at least part of the second electrode portion on the first substrate.

28. The display panel according to claim 27, wherein the second electrode portion comprises: a first sub-portion and a second sub-portion disposed opposite to each other;
the first sub-portion comprises: a first main portion extending in the first direction, and a plurality of first branch portions extending out from the first main portion in the second direction;
the second sub-portion comprises: a second main portion extending in the first direction, and a plurality of second branch portions extending out from the second main portion in the second direction; and the first branch portions intersect with the second branch portions.

29. The display panel according to claim 28, wherein the at least one temperature sensor comprises: two first electrode portions arranged in the first direction, two active portions arranged in the first direction, and two second electrode portions arranged in the first direction;
the two first electrode portions are spaced apart and independent of each other;
the two active portions are spaced apart and independent of each other;
the two second electrode portions share a same first main portion, and the second main portions of the two second electrode portions are spaced apart and independent of each other.

30. The display panel according to claim 28, further comprising: a plurality of sensor leads; wherein the plurality of sensor leads comprises: a first routing, wherein one end of the first routing is electrically connected with the first electrode portion and extends towards a side far away from the display area; a second routing, wherein one end of the second routing is electrically connected with the first main portion and extends towards the side far away from the display area; and a third routing, wherein one end of the third routing is electrically connected with the second main portion and extends towards the side far away from the display area;
wherein the display panel further comprises: a pin group electrically connected with the routing group, and a floating pin group on an outside of the pin group; the floating pin group comprises a first floating pin, a second floating pin, and a third floating pin;
an other end of the first routing is electrically connected with the first floating pin, an other end of the second routing is electrically connected with the second floating pin, and an other end of the third routing is electrically connected with the third floating pin.

31. The display panel according to claim 29, wherein the second routing comprises: a first sub-routing portion, and a second sub-routing portion; the third routing comprises: a third sub-routing portion, and a fourth sub-routing portion;
wherein the display panel further comprises: a first adapter portion and a second adapter portion; the first sub-routing portion, the second sub-routing portion, and the first adapter portion are on different layers, and the third sub-routing portion, the fourth sub-routing portion, and the second adapter portion are on different layers;
an orthographic projection of the first adapter portion on the first substrate covers an orthographic projection of a part of the first sub-routing portion on the first substrate, and an orthographic projection of a part of the second sub-routing portion on the first substrate; and the first sub-routing portion and the second sub-routing portion are connected through the first adapter portion for conduction;
an orthographic projection of the second adapter portion on the first substrate covers an orthographic projection of a part of the third sub-routing portion on the first substrate, and an orthographic projection of a part of the fourth sub-routing portion on the first substrate; and the third sub-routing portion and the fourth sub-routing portion are connected through the second adapter portion for conduction.

32. The display panel according to claim 31, wherein the first sub-routing portion, the third sub-routing portion and the second electrode portion are of a same layer and a same material;
the second sub-routing portion, the fourth sub-routing portion and the first electrode portion are of a same layer and a same material;
the first routing and the first electrode portion are of a same layer and a same material.

33. The display panel according to claim 32, wherein the data lines are disposed on one sides of the gate lines facing away from the first substrate; the display panel comprises: a pixel electrode and/or a common electrode disposed on one sides of the data lines facing away from the gate lines;
the first electrode portion is of a same layer and a same material as the gate lines;
the second electrode portion is of a same layer and a same material as the data lines;
the first adapter portion and the second adapter portion are of a same layer and a same material as the pixel electrode or common electrode.

34. The display panel according to claim 31, wherein at least one of the second sub-routing portion and the fourth sub-routing portion is provided with a plurality of hollow areas.

35. The display panel according to claim 30, wherein the pin group comprises: a plurality of first sub-pins, and a plurality of second sub-pins disposed on both sides of the plurality of first sub-pins;
the display panel further comprises: a common routing, wherein the data line is electrically connected with the first sub-pin, and the common routing is electrically connected with the second sub-pin.

36. The display panel according to claim 35, wherein the common routing is provided with a first hollow portion, at least part of the common routing is in an area between two adjacent fan-shaped routing areas;
an orthographic projection of the temperature sensor on the first substrate is in an orthographic projection of the first hollow portion on the first substrate;
wherein the common routing is further provided with a plurality of second hollow portions, an area of the first hollow portion is larger than an area of the second hollow portion, and the common routing is of a same layer and a same material as the first electrode portion.

37. The display panel according to claim 27, wherein a shape of an orthographic projection of the active portion on the first substrate is a rectangle;
wherein the routing group comprises a plurality of leads;
a distance between adjacent sensor leads is 1.5 to 5 times of a distance of adjacent leads; and a line width of the sensor lead is 5 to 10 times of a line width of the lead.

38. The display panel according to claim 26, further comprising: at least one light sensor, wherein the light sensor is on the same side of the display area as the fan-shaped routing area, and the light sensor is in an area outside of the fan-shaped routing area; and the light sensor is configured to detect brightness to adjust brightness of the display panel based on the detected brightness.

39. The display panel according to claim 38, wherein the light sensor has a same structure as the temperature sensor.

40. The display panel according to claim 38, wherein the light sensor comprises two sub-light sensors;
the display panel further comprises a black matrix layer, wherein the black matrix layer is provided with a first black matrix opening, an orthographic projection of one sub-light sensor of the light sensor on the first substrate is within the first black matrix opening, and an other sub-light sensor is obscured by the black matrix layer.

41. The display panel according to claim 36, wherein a shape of an outer contour of an active portion in the sub-light sensor is square.

42. The display panel according to claim 26, wherein the display panel has a first symmetry axis; the first symmetry axis passes through a center of the at least one temperature sensor.

43. The display panel according to claim 42, wherein the display panel further comprises: a first side area opposite to the fan-shaped routing area, and a second side area and a third side area which are connected a side, where the fan-shaped routing area is located, with the first side area; the first side area, the second side area, and the third side area are located in an area on one side of the display area;
at least one of the first side area, the second side area and the third side area is provided with the temperature sensor;
wherein the first electrode portion of at least one of the temperature sensor and the light sensor is configured to load a square wave signal to turn on the temperature sensor at intervals of a preset length of time, and/or to turn on the light sensor at intervals of a preset length of time.

44. A display device, comprising a display panel, wherein the display panel comprises: a display area, and a plurality of fan-shaped routing areas on a side of the display area, wherein the display panel comprises:
a plurality of gate lines, extending in a first direction, and in the display area;
a plurality of data lines, extending in a second direction, intersecting with the plurality of gate lines, and in the display area;
a plurality of routing groups, wherein at least one of the plurality of routing groups is disposed in at least one of the plurality of fan-shaped routing areas, and at least part of the plurality of routing groups is electrically connected with the plurality of data lines;
at least one temperature sensor, on a same side of the display area as the fan-shaped routing areas, wherein at least part of the at least one temperature sensor is in an area between two adjacent fan-shaped routing areas;
wherein the temperature sensor is configured to detect an ambient temperature, so that the display panel loads a voltage on the data lines based on a temperature detected by the temperature sensor.

45. The display device according to claim 44, further comprising a first circuit board electrically connected with the display panel; wherein the first circuit board is provided with a first processor to process a temperature signal detected by the temperature sensor to form a first signal;
wherein the display device further comprises a second circuit board on a side of the first circuit board far away from the display panel and electrically connected with the first circuit board;
wherein the second circuit board comprises: a second processor configured to process the first signal to form a second signal;
the display device further comprises: a third processor, wherein the third processor at least stores a first storage table corresponding to a room temperature, a second storage table corresponding to a first threshold, and a third storage table corresponding to a second threshold;
the third processor is configured to call the first storage table, the second storage table, or the third storage table based on the second signal to load a voltage to the data lines according to grayscales of the first storage table, the second storage table, or the third storage table;
wherein the display device further comprises a backlight source on a backlight side of the display panel, and a fourth processor;
wherein the fourth processor is configured to adjust brightness of the backlight source based on a signal detected by the light sensor.
